(19) United States
(12) Patent Application Publication
(10) Pub. No.: US 2019/0019902 A1
(43) Pub. Date: Jan. 17, 2019

(54) SILICON WAVEGUIDE INTEGRATED WITH GERMANIUM PIN PHOTODETECTOR

(71) Applicants: Jinlin Ye, Eastvale, CA (US); Shirong Liao, Eastvale, CA (US)

(72) Inventors: Jinlin Ye, Eastvale, CA (US); Shirong Liao, Eastvale, CA (US)

(21) Appl. No.: 16/035,572

(22) Filed: Jul. 13, 2018

Related U.S. Application Data
(60) Provisional application No. 62/532,277, filed on Jul. 13, 2017.

(51) Int. Cl. H01L 31/0232; G02B 6/136; H01L 31/028; H01L 31/105; H01L 31/18

(52) U.S. Cl. CPC H01L 31/02327; G02B 6/136; G02B 2006/12138; H01L 31/105; H01L 31/1808; H01L 31/028

(57) ABSTRACT

A method for manufacturing an integrated photodetector may include steps of providing a silicon-insulator substrate including a top layer, an insulator layer, and a base layer; partially removing the top layer to form an optical waveguide over the insulator layer; forming an opening at least through the cladding layer and the insulator layer extending to a first portion of the base layer; and epitaxially growing a lattice-mismatched semiconductor layer over the first portion of the base layer at least in the opening, at least a portion of the semiconductor layer extending above the insulator layer to form a photodetector including an intrinsic region optically coupled to the waveguide. In one embodiment, the intrinsic region of the photodetector is butt-coupled to the optical waveguide. In another embodiment, the intrinsic region of the photodetector is evanescently coupled to the optical waveguide.

### CROSS-REFERENCE TO RELATED APPLICATIONS

This application claims priority under 35 U.S.C. § 119 (e) to U.S. Provisional Patent Application Ser. No. 62/532,277, filed on Jul. 13, 2017, the entire contents of which are hereby incorporated by reference.

### FIELD OF THE INVENTION

The present invention relates to an integrated waveguide photodetector, and more particularly to a silicon waveguide integrated with Germanium (Ge) photodetector.

### BACKGROUND OF THE INVENTION

The substantial growth in web based multimedia and social networking applications is putting a significantly larger amount of data traffic on the current telecom and data infrastructure. This is leading to significant connectivity bottlenecks. It is widely accepted that silicon photonics, due to its electronics integration capability, proven manufacturing record and price-volume curve, will be the platform of choice for the next generation interconnect and communication solutions to address the connectivity bottlenecks. This has fueled significant research and development work in this area in the past few years.

Many silicon-based active photonics components, such as high-speed modulators and Germanium (Ge) photodetectors have been demonstrated on submicron waveguides. However, submicron silicon waveguides still suffer from high fiber coupling loss, high polarization dependent loss, and large waveguide birefringence and phase noise. As a result, they do not provide a satisfactory platform for implementation of passive and wavelength-division-multiplexing devices. On the other hand, many high performance optical components have been demonstrated for large cross-section silicon waveguides, such as arrayed waveguide gratings, Echelle gratings, and Triplexer filters exhibiting low fiber coupling loss, low waveguide propagation loss, low polarization dependent loss, and low polarization dependent frequency shift. Therefore, there is a need for a compact, high-speed photodetector integrated with large cross-section silicon waveguides to incorporate the benefits stated above.

### SUMMARY OF THE INVENTION

It is an object of the present invention to provide a silicon waveguide integrated with Germanium (Ge) photodetector.

It is another object of the present invention to provide a compact, high speed Ge photodetector efficiently butt-coupled with a large cross-section silicon waveguide.

It is a further object of the present invention to provide a compact, high speed Ge photodetector butt-coupled with a large cross-section silicon waveguide based on a PIN junction with the Ge waveguide grown over the large cross-section silicon waveguide.

In one aspect, fabrication of the integrated waveguide-based photodetector having lateral PIN configuration may include a substrate having a base semiconductor layer and an insulator layer disposed thereon. The insulator layer may serve as a bottom cladding layer of the waveguide. Furthermore, a top semiconductor layer is disposed over the insulator layer. In a particular embodiment, the substrate is an SOI (Silicon on Insulator) wafer such that the top and the base semiconductor layers consist essentially of single-crystal silicon and the insulator layer consists essentially of silicon dioxide. A waveguide is defined on the layer, for example, by masking the desired configuration of the waveguide using a patterned photoresist layer and then etching the exposed portions of the layer. In one embodiment, the photodetector can be fabricated on six-inch SOI wafers with 0.375 μm thick buried oxide (BOX) and a 3 μm thick silicon epitaxial layer.

Furthermore, an opening is then defined on the substrate. In one embodiment, the opening can be formed by etching the top semiconductor layer. More specifically, the opening can be formed by etching the top semiconductor layer down to 0.6 μm above the insulator layer. The opening can be formed by any method known in the art, for example, by applying a patterned photoresist layer over the top semiconductor layer followed by etching of portions of the layers exposed by the photoresist.

In some embodiments, the opening has a first doped area that can then be doped by any of the methods known in the art, for example, by dopant implantation. Examples of suitable dopants are n-type dopants such as phosphorus, arsenic, and antimony, or a p-type dopant, such as boron. Dopant ions may be implanted by directing a dopant-containing gas, such as phosphine, arsine, stibine, and/or diborane, at the exposed portion of the top layer. In other embodiments, the dopant gas is typically diluted in a carrier gas to, for example, approximately 1% concentration. In some embodiments, the opening is formed through the waveguide such that a butt end of the waveguide is part of the sidewall of the opening.

A photodetector layer in the opening at least partially over the first doped area. In some embodiments, the photodetector layer may include a lattice-mismatched semiconductor material. In some embodiments, as mentioned above, in order to reduce the effective thickness of the photodetector layer thereby enhancing the detection speed, a thin layer of the same semiconductor material as the material of the base layer, for example, silicon, is deposited over the first doped region, followed by the deposition of the lattice-mismatched semiconductor material. The lattice-mismatched semiconductor material is selected depending, in part, on the desired optical absorption properties of the photodetector material for a given wavelength. In various embodiments, the lattice-mismatched semiconductor material is bulk germanium (Ge) or a silicon-germanium alloy having a germanium concentration exceeding about 90%. As skilled artisans will readily recognize, for typical wavelengths used in optoelectronic applications, the optical absorption coefficient of bulk germanium (Ge) disposed over silicon substrate is very high—e.g. about 9000 cm⁻¹ for a wavelength of about 1.3 μm and between 2000 and 4000 cm⁻¹ for a wavelength of about 1.55 μm. In the present invention, Ge is used for the photodetector layer.

In an exemplary embodiment, a 100 nm thick Ge buffer layer was selectively grown at 400° C., followed by 4 μm thick Ge growth at 670° C. in the opening. It is noted that the Ge film may be intentionally over grown, then thinned down and planarized with a chemical-mechanical polishing (CMP) step. A final Ge thickness of 2.4 μm was achieved after CMP. The wafers then underwent a Ge anneal to reduce the threading dislocation density in the Ge film. As the etching rate of Ge is greater than that of silicon, additional etching in the silicon region can be performed, forming a silicon ridge waveguide with a 0.6 μm thick slab and a Ge ridge waveguide with a 0.2 μm thick slab.

The Ge waveguide can be doped by, for example, boron and phosphorus in the sidewalls and slabs to form a horizontal p-i-n junction and p-type and n-type Ohmic contact areas. After rapid thermal annealing dopant activation, the Ti/Al metal stack was deposited and patterned to form p-type and n-type metal contacts. Finally, oxide and nitride films were deposited as waveguide cladding and passivation layers.

In one embodiment, the Ge photodetector layer can be 100% butt-coupled with the Si waveguide. In another embodiment, the Ge photodetector layer can be partially butt-coupled and partially evanescent-coupled with the Si waveguide.

In another aspect, a method for manufacturing an integrated photodetector may include steps of providing a silicon-insulator substrate including a top layer, an insulator layer and a base layer; partially removing the top layer to form an optical waveguide over the insulator layer; forming an opening at least through the cladding layer and the insulator layer extending to a first portion of the base layer; and epitaxially growing a semiconductor layer over the first portion of the base layer at least in the opening, at least a portion of the semiconductor layer extending above the insulator layer to form a photodetector including an intrinsic region optically coupled to the waveguide.

### BRIEF DESCRIPTION OF THE DRAWINGS

FIG. 1 is a schematic view of the photodetector having a silicon waveguide in the present invention.

FIG. 2 is a schematic view of the photodetector defining an opening for a photodetector layer that may be butt-coupled with the silicon waveguide in the present invention.

FIG. 3 is a schematic view of the photodetector that the photodetector layer is butt-coupled with the silicon waveguide in the present invention.

FIG. 4 is a cross-section view of the photodetector that the photodetector layer is butt-coupled with the silicon waveguide in the present invention.

FIG. 5 is a schematic view of the photodetector that the photodetector layer is butt-coupled with the silicon waveguide in which the photodetector layer is wider than the silicon waveguide in the present invention.

FIG. 6 is a schematic view of the photodetector that the photodetector layer is butt-coupled with the silicon waveguide in which the photodetector layer is narrower than the silicon waveguide in the present invention.

FIG. 7 is a schematic view of the photodetector that the photodetector layer is butt-coupled with the silicon waveguide in which the photodetector layer is taller than the silicon waveguide in the present invention.

FIG. 8 is a method for manufacturing an integrated photodetector in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

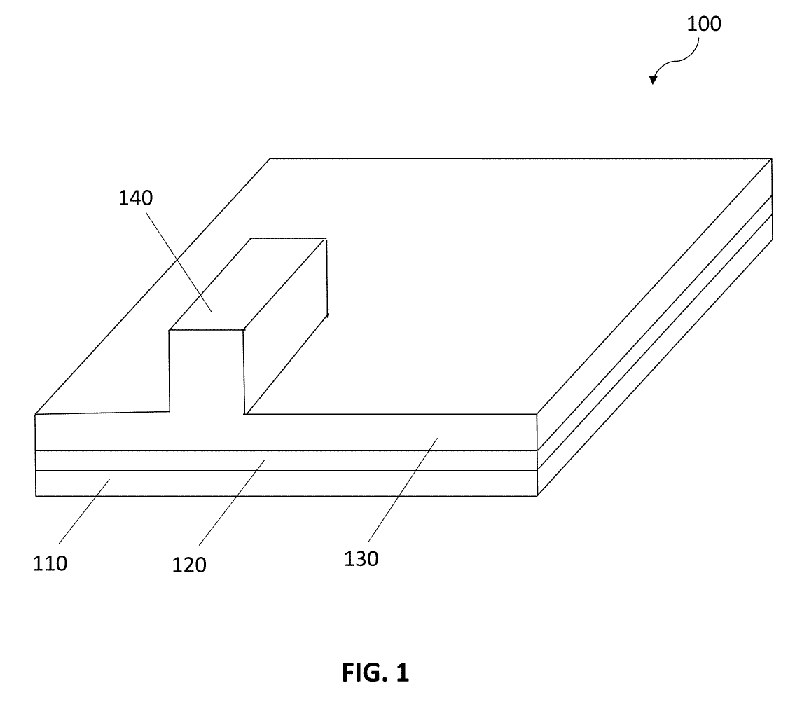

In one aspect, as shown in FIG. 1, fabrication of the integrated waveguide-based photodetector 100 having lateral PIN configuration may include a substrate having a base semiconductor layer 110 and an insulator layer 120 disposed thereon. The insulator layer 120 may serve as a bottom cladding layer of the waveguide. Furthermore, a top semiconductor layer 130 is disposed over the insulator layer 120. In a particular embodiment, the substrate 100 is an SOI (Silicon on Insulator) wafer such that the top and the base semiconductor layers consist essentially of single-crystal silicon and the insulator layer consists essentially of silicon dioxide. A waveguide 140 is defined on the layer 130, for example, by masking the desired configuration of the waveguide using a patterned photoresist layer and then etching the exposed portions of the layer 130. In one embodiment, the photodetector 100 can be fabricated on six-inch SOI wafers with 0.375 μm thick buried oxide (BOX) and a 3 μm thick silicon epitaxial layer.

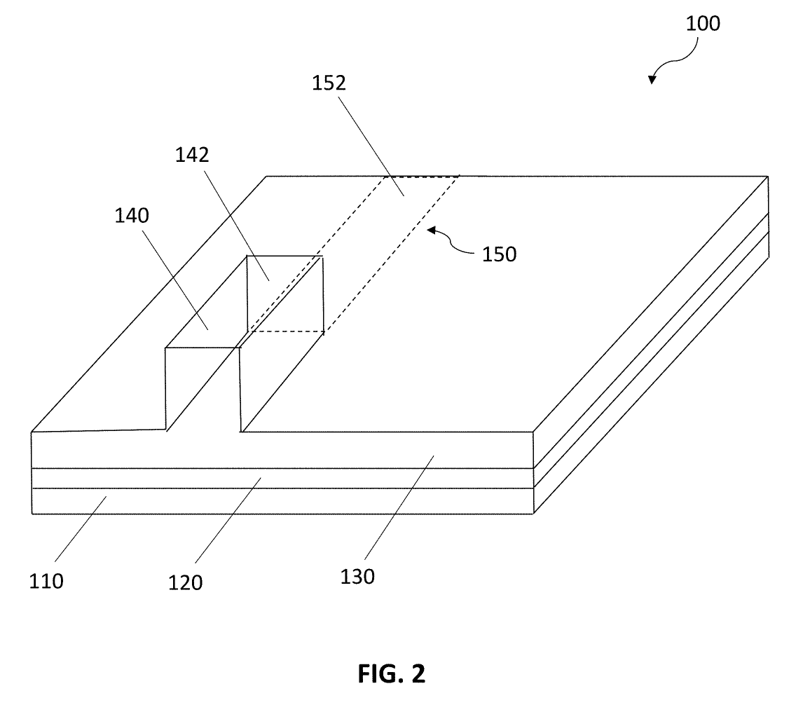

Referring to FIG. 2, an opening 150 is then defined on the substrate. In one embodiment, the opening 150 can be formed by etching the top semiconductor layer 130. More specifically, the opening 150 can be formed by etching the top semiconductor layer 130 down to 0.6 μm above the insulator layer 120. The opening 150 can be formed by any method known in the art, for example, by applying a patterned photoresist layer over the top semiconductor layer followed by etching of portions of the layers exposed by the photoresist.

In some embodiments, the opening 150 has a first doped area 152 that can then be doped by any of the methods known in the art, for example, by dopant implantation. Examples of suitable dopants are n-type dopants such as phosphorus, arsenic, and antimony, or a p-type dopant, such as boron. Dopant ions may be implanted by directing a dopant-containing gas, such as phosphine, arsine, stibine, and/or diborane, at the exposed portion of the top layer. In other embodiments, the dopant gas is typically diluted in a carrier gas to, for example, approximately 1% concentration. In some embodiments, the opening 150 is formed through the waveguide such that a butt end 142 of the waveguide 140 is part of the sidewall of the opening.

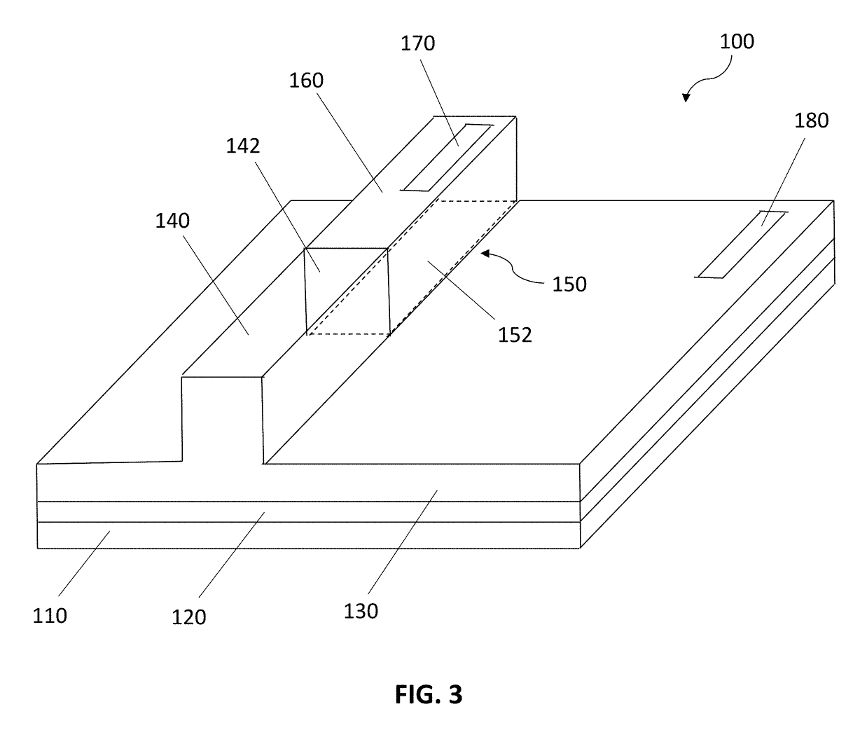

As shown in FIG. 3, a photodetector layer 160 in the opening 150 at least partially over the first doped area 152. In some embodiments, the photodetector layer 160 may include a lattice-mismatched semiconductor material. In some embodiments, as mentioned above, in order to reduce the effective thickness of the photodetector layer thereby enhancing the detection speed, a thin layer of the same semiconductor material as the material of the base layer 110, for example, silicon, is deposited over the first doped region, followed by the deposition of the lattice-mismatched semiconductor material. The lattice-mismatched semiconductor material is selected depending, in part, on the desired optical absorption properties of the photodetector material for a given wavelength. In various embodiments, the lattice-mismatched semiconductor material is bulk germanium (Ge) or a silicon-germanium alloy having a germanium concentration exceeding about 90%. As skilled artisans will readily recognize, for typical wavelengths used in optoelectronic applications, the optical absorption coefficient of bulk germanium (Ge) disposed over silicon substrate is very high—e.g. about 9000 cm⁻¹ for a wavelength of about 1.3 m and between 2000 and 4000 cm⁻¹ for a wavelength of about 1.55 m. In the present invention, Ge is used for the photodetector layer 160.

In an exemplary embodiment, a 100 nm thick Ge buffer layer was selectively grown at 400° C., followed by 4 μm thick Ge growth at 670° C. in the opening 150. It is noted that the Ge film may be intentionally over grown, then thinned down and planarized with a chemical-mechanical polishing (CMP) step. A final Ge thickness of 2.4 μm was achieved after CMP. The wafers then underwent a Ge anneal to reduce the threading dislocation density in the Ge film. As the etching rate of Ge is greater than that of silicon, additional etching in the silicon region can be performed, forming a silicon ridge waveguide with a 0.6 μm thick slab and a Ge ridge waveguide with a 0.2 μm thick slab.

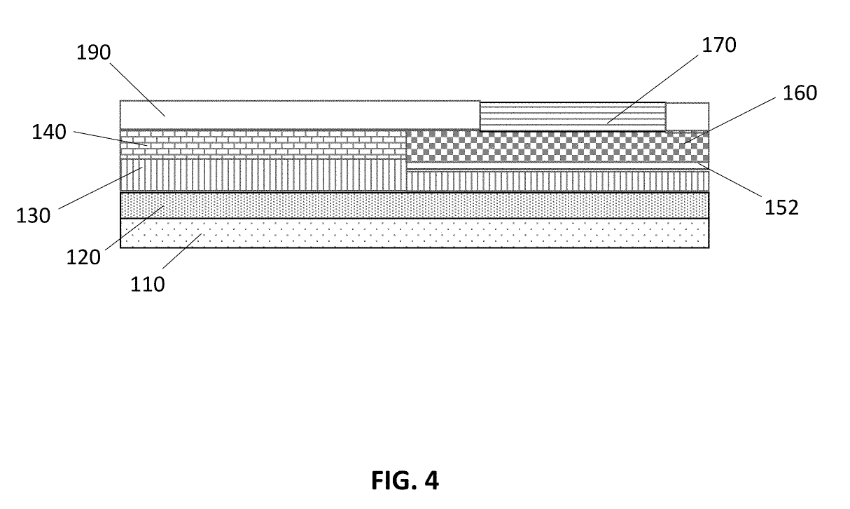

The Ge waveguide can be doped by, for example, boron and phosphorus in the sidewalls and slabs to form a horizontal p-i-n junction and p-type and n-type Ohmic contact areas. After rapid thermal annealing dopant activation, the Ti/Al metal stack was deposited and patterned to form p-type and n-type metal contacts 170 and 180. Finally, oxide and nitride films were deposited as waveguide cladding and passivation layers 190. A cross-section view of the photodetector 100 can be seen in FIG. 4.

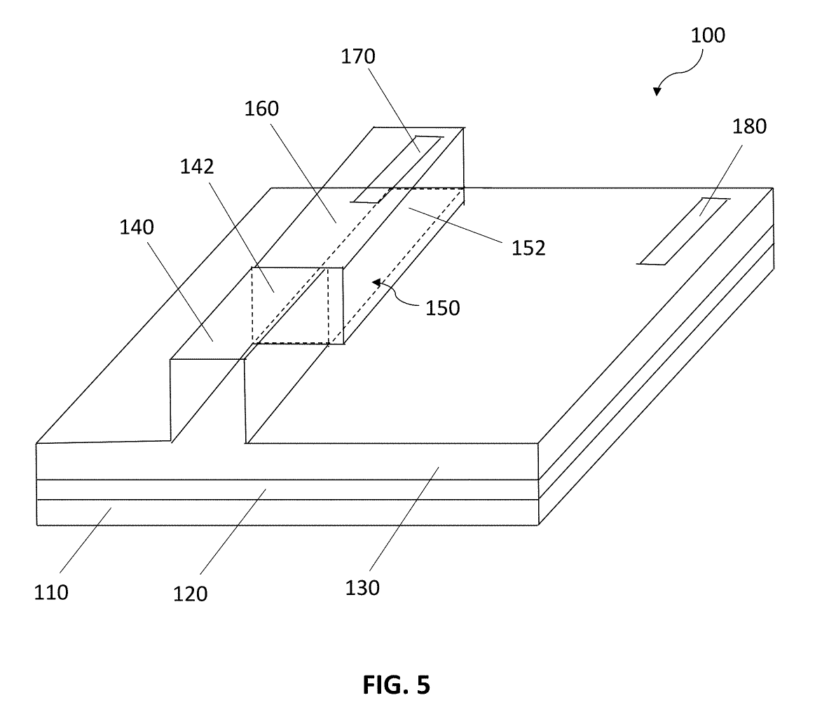

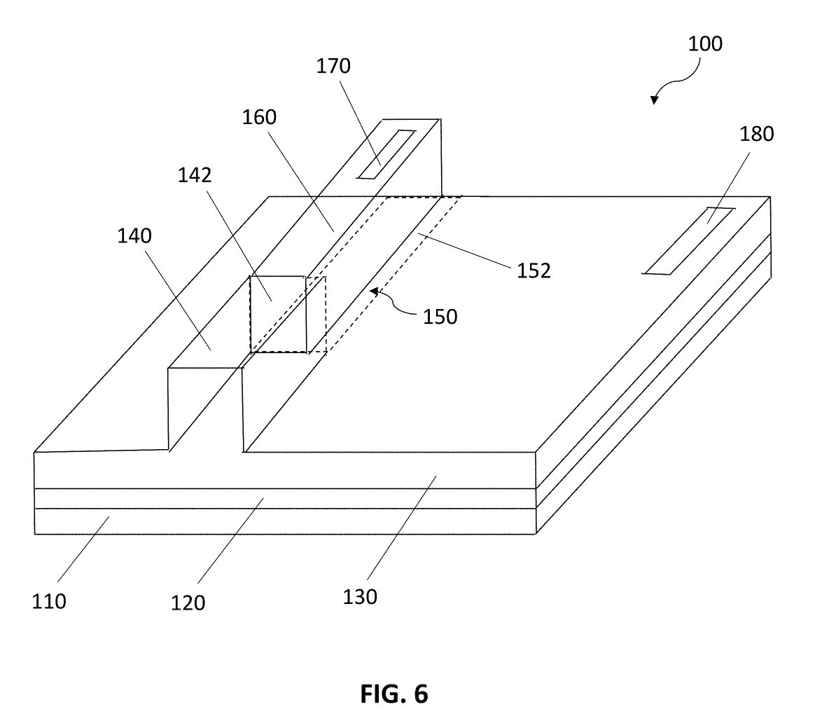

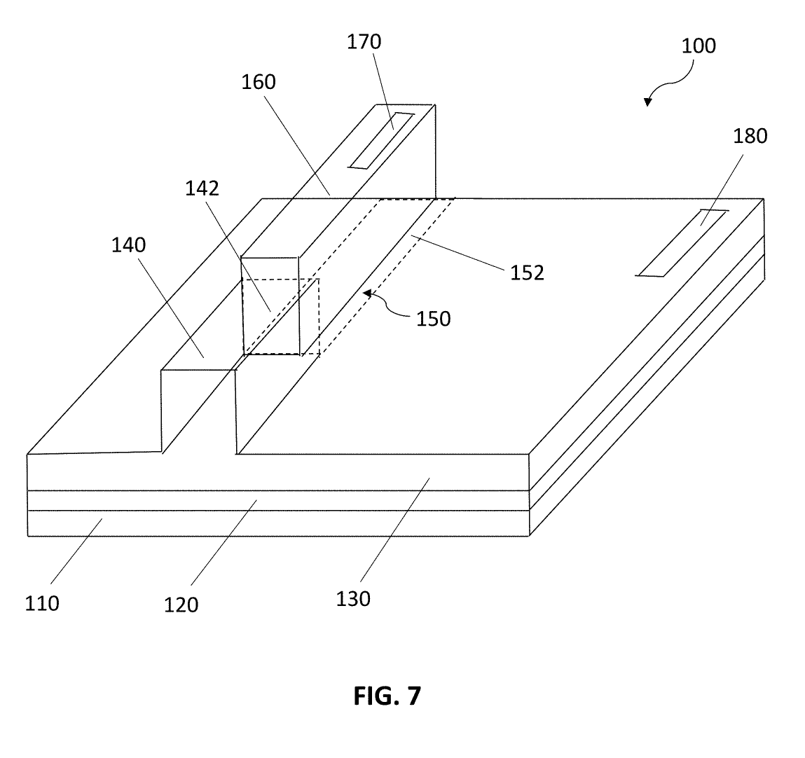

In one embodiment, the Ge photodetector layer 160 can be 100% butt-coupled with the Si waveguide 140, as shown in FIG. 3. In another embodiment, the Ge photodetector layer 160 can be partially butt-coupled and partially evanescent-coupled with the Si waveguide 140. As shown in FIG. 5, the Ge photodetector layer 160 is wider than the Si waveguide 140. In one embodiment, the Ge photodetector layer 160 can be wider than the Si waveguide 140 by 1 to 8 μm. On the other hand, the Si waveguide 140 can be wider than the Ge photodetector layer 160 by a range of 1 to 8 μm as shown in FIG. 6. The Ge photodetector layer 160 can also be taller than the Si waveguide 140 as shown in FIG. 7. It is noted that the performance of the photodetector in the present invention can be designed for wide range of 3 dB bandwidth, such as 5 GHz, 10 GHz, 25 GHz and 40 GHz.

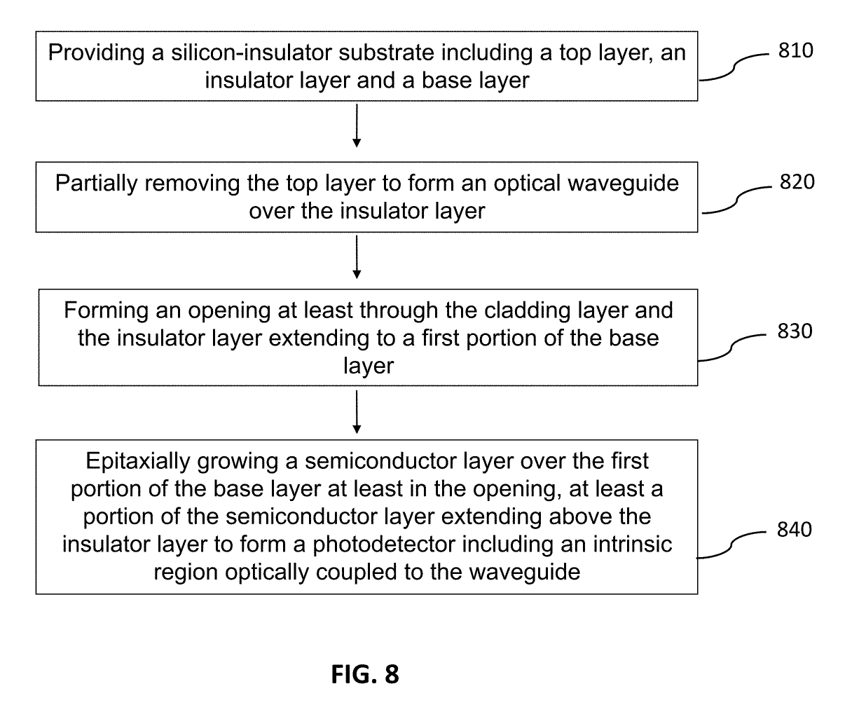

In another aspect, as shown in FIG. 8, a method for manufacturing an integrated photodetector may include steps of providing a silicon-insulator substrate including a top layer, an insulator layer and a base layer 810; partially removing the top layer to form an optical waveguide over the insulator layer 820; forming an opening at least through the cladding layer and the insulator layer extending to a first portion of the base layer 830; and epitaxially growing a semiconductor layer over the first portion of the base layer at least in the opening, at least a portion of the semiconductor layer extending above the insulator layer to form a photodetector including an intrinsic region optically coupled to the waveguide 840.

In one embodiment, the step 830 of forming an opening at least through the cladding layer and the insulator layer extending to a first portion of the base layer further includes a step of forming a first doped area in the first portion of the base layer. In another embodiment, the method for manufacturing an integrated photodetector further includes a step of forming a source region and a drain region in the photodetector 850 and forming contact regions electrically coupled to the source and drain regions 860. In a further embodiment, the semiconductor layer in step 840 is made by germanium.

In an exemplary embodiment, the intrinsic region of the photodetector is butt-coupled to the optical waveguide. In an alternative embodiment, the intrinsic region of the photodetector is evanescently coupled to the optical waveguide. In still a further embodiment, the step 840 of epitaxially growing a semiconductor layer further comprises annealing the semiconductor material.

While generally described in connection with germanium or silicon-germanium photodetectors integrated with silicon or silicon-based optical waveguides employing silicon or SOI wafers as starting substrates, the invention is not thusly limited and other materials and starting substrates are contemplated without departing from the scope or spirit of the invention.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. An integrated photodetector comprising: a substrate comprising a first insulator layer disposed over a base layer, the base layer comprising a first semiconductor material, the first cladding layer defining an opening extending to the base layer; an optical waveguide comprising the first semiconductor material and disposed over the substrate; and a photodetector comprising a second semiconductor material epitaxially grown over the base layer at least in the opening, the photodetector comprising an intrinsic region optically coupled to the waveguide, at least a portion of the intrinsic region extending above the first cladding layer and aligned with the waveguide.

2. The integrated photodetector of claim 1, wherein the intrinsic region of the photodetector is butt-coupled to the optical waveguide.

3. The integrated photodetector of claim 1, wherein the intrinsic region of the photodetector is evanescently coupled to the optical waveguide.

4. The integrated photodetector of claim 1, wherein the second semiconductor material is germanium.

5. The integrated photodetector of claim 1, wherein the photodetector can be doped by boron and phosphorus to form a horizontal p-i-n junction.

6. The integrated photodetector of claim 1, wherein the photodetector can be wider than the optical waveguide.

7. A method for manufacturing an integrated photodetector comprising steps of providing a silicon-insulator substrate including a top layer, an insulator layer and a base layer; partially removing the top layer to form an optical waveguide over the insulator layer; forming an opening at least through the cladding layer and the insulator layer extending to a first portion of the base layer; and epitaxially growing a semiconductor layer over the first portion of the base layer at least in the opening, at least a portion of the semiconductor layer extending above the insulator layer to form a photodetector including an intrinsic region optically coupled to the waveguide.

8. The method for manufacturing an integrated photodetector of claim 7, wherein the step of forming an opening at least through the cladding layer and the insulator layer extending to a first portion of the base layer further includes a step of forming a first doped area in the first portion of the base layer.

9. The method for manufacturing an integrated photodetector of claim 7, further includes a step of forming a source region and a drain region in the photodetector and forming contact regions electrically coupled to the source and drain regions.

10. The method for manufacturing an integrated photodetector of claim 7, wherein the intrinsic region of the photodetector is butt-coupled to the optical waveguide.

11. The method for manufacturing an integrated photodetector of claim 7, wherein the intrinsic region of the photodetector is evanescently coupled to the optical waveguide.

12. The method for manufacturing an integrated photodetector of claim 7, wherein the semiconductor layer is made by germanium.
